(19) United States
(12) Patent Application Publication
(10) Pub. No.: US 2025/0392253 A1
(43) Pub. Date: Dec. 25, 2025

(54) Leporello Fold-Type Solar Installation and Method for Setting Up the Solar Installation

(71) Applicant: Richard Meyer, Altmarkt (DE)

(72) Inventor: Richard Meyer, Altmarkt (DE)

(21) Appl. No.: 18/879,447

(22) PCT Filed: Jun. 26, 2023
(86) PCT No.: PCT/EP2023/067317

§ 371 Date: Dec. 27, 2024

(30) Foreign Application Priority Data
Jun. 30, 2022 (DE) 10 2022 116 412.8

(51) Int. Cl. H02S 30/20; H02S 20/30

(52) U.S. Cl. CPC H02S 30/20; H02S 20/30

(57) ABSTRACT

The present disclosure relates to a solar plant with solar panels (2, 2′) which are prefabricated in a leporello folding (3) which can be unfolded in an unfolding direction (A), and a substructure on which the solar panels are arranged, wherein the substructure is designed to be flexible in the unfolding direction (A) and is connected to the solar panels in a positionally fixed manner in such a way that the leporello folding (3) of the solar panels can be unfolded with the substructure (8, 9, 10, 24) and determines angular positions of the solar panels (2, 2′) relative to one another.

The invention relates to solar plants with solar panels that are pre-assembled in a leporello folding, as well as a method for assembling the solar plant.

WO 2014/179893 A1 discloses a solar plant with a plurality of solar panels arranged in a row. The solar panels are folded as a leporello folding and can be unfolded along guide rods. The arrangement is mounted on two supports on the ground. The disadvantage here is that a separate support structure is required.

CH 705 633 A1 discloses a photovoltaic plant with a plurality of solar modules arranged at a distance from one another, which disadvantageously are unfolded along a support, in particular a support cable, which is to be installed separately.

DE 10 2015 121 200.5 discloses a method for building a roof structure comprising solar panels for mobile solar power plants on a ground surface. The solar panels are folded as leporello foldings and are then extended along rails mounted on supports to form a roof surface. The disadvantage of this method is that it is only suitable for constructing a solar power plant with a relatively complex rail support system.

It is therefore the task of the present invention to provide a solar plant which can be positioned at several locations, for example on roof surfaces, ground or water surfaces, and which is also easier to install.

It is also the task of the present invention to provide a method for constructing a solar plant which can be used in several locations and is easy to carry out.

The task is fulfilled in its first embodiment by a solar plant referred to at the beginning with the features of claim 1.

The solar plant according to the invention comprises solar panels which form a leporello folding which can be unfolded in an unfolding direction and preferably folded in against the unfolding direction. The foldable solar plant comprises a substructure on which the solar panels are arranged, wherein the substructure is flexible, preferably flexible in the unfolding direction and is connected to the solar panels in a positionally fixed manner in such a way that the leporello folding of the solar panels can be unfolded with the substructure and determines angular positions of the solar panels relative to one another.

The solar plant can explicitly be deployed in several directions. The one unfolding direction is only one of several unfolding directions.

The substructure is preferably flexible along its entire length in the unfolding direction.

A leporello folding is understood here to mean solar panels arranged in a zigzag fold, whereat the solar panels are arranged in a row in the unfolding direction and are flexibly hinged together along longitudinal edges transverse to the unfolding direction. The folding is preferably perpendicular to the unfolding direction. Preferably, each solar panel has an edge on the substructure side and an edge on the off-substructure side. These are edges that are arranged transverse to the unfolding direction, whereat two directly adjacent solar panels are hinged together either by means of two edges on the substructure side or by means of two edges on the off-substructure side.

All segments of the leporello folding can be designed as solar panels. It is also conceivable that a single or periodically preferably every second segment has no solar panels, but is a filling surface or is designed as a framework.

The substructure is designed to be flexible in the unfolding direction. It can also be flexible in other directions. The substructure is flexible in the folded state and can also be flexible in the unfolded state and during operation. However, the substructure can also change its state during operation and in the unfolded state and be fixed.

The leporello folding of the solar panels can preferably be unfolded automatically with the substructure. When the substructure is unfolded, the solar panels are also unfolded automatically.

Preferably, the substructure extends over the entire unfolded length of the solar plant when unfolded. The substructure is also a foundation that can bear the total load of the solar plant.

The leporello folding is fixed in position, preferably at fixing points on the substructure. This means that the leporello folding can be unfolded with the substructure and an angular position of the solar panels relative to each other is determined. When the substructure is fully unfolded, the solar panels assume a specific angular position relative to each other, which is determined by the attachment points of the solar panels on the substructure, the length of the solar panels in the unfolding direction and the distance between the attachment points.

The substructure can be designed in different ways. It preferably has at least one hollow body that runs in the unfolding direction and can be filled with a medium. The medium is preferably a gas such as air or nitrogen or a foam that hardens. The hollow bodies preferably have a flexible, preferably fully flexible surrounding wall and they are preferably foldable.

Preferably, the hollow body filled with the medium generates sufficient buoyancy to hold the solar panels above the surface of a body of water in which the solar plant floats.

The filled hollow body has a buoyancy in the water that is so great that the leporello folding remains permanently positioned above a water surface. Preferably, the solar plant floats on the water when in operation and is secured against drifting by anchors, ropes or similar means.

In another preferred embodiment, the substructure has a flexible sheet running in the direction of unfolding.

The term “sheet” is to be understood broadly. The at least one sheet can comprise at least one belt or at least one textile sheet or plastic film or at least one rope.

The leporello folding is preferably glued to the substructure. However, it is also conceivable that the leporello folding is detachably attached to the substructure, preferably by means of Velcro fasteners. The distance between the attachment points of the leporello folding on the substructure preferably permanently determines an angle of inclination of the leporello folding relative to the substructure. The angle of inclination is typically between 5° and 30°. A flat arrangement of 0° is also possible. Steeper angles of inclination lead to a reduction in electricity production when the sun is at its highest, but to higher yields in the morning and evening and allow the inverter power to be dimensioned smaller. Higher inclinations also lead to better cleaning in the rain and less dirt deposits.

In another embodiment of the invention, the at least one hollow body serves as a support for the leporello folding on a non-solid surface. This can be a moist surface such as a moor or mudflat or also a largely dry surface such as a soil, but also a flat roof of a building. In these embodiments, the at least one hollow body can also be smaller or differently dimensioned than in the buoyant variants because it does not have to generate buoyancy for the leporello folding.

The flexible sheet can be a textile and plastic sheet, for example. The solar plant is preferably positioned on a solid surface. The leporello folding is preferably arranged completely on the flexible sheet and preferably does not protrude to the side, front or rear in the unfolding direction. The sheet can be designed to reflect light in order to reflect light passing through the solar panels or scattered light onto the solar panels from behind. When implemented with bifacial solar modules, the yield is thus additionally increased if the albedo of the membrane is greater than that of the surface.

The hollow body that can be filled with a medium is preferably two, preferably a plurality, of hoses arranged next to each other transversely to the unfolding direction and each extending in the unfolding direction.

Preferably, the hoses are arranged at lateral sections of the leporello folding perpendicular to the unfolding direction, preferably at quarter points.

The hoses can each have a number of gas-tight chambers. Several gas-tight chambers can be connected to each other, for example by pumps.

The hollow bodies can also be filled with foam to provide a stable substructure that continues to generate sufficient buoyancy in the water even when during a drop in pressure.

Preferably, the hollow bodies can changeably be filled with granulate or ballasting liquid. In the case of floating solar plants, the amount of ballasting liquid can be adapted to the sea state. In the case of solar plants positioned on roofs, but also positioned on the ground, the quantity of ballasting liquid can be adapted to the wind conditions at the location or temporarily reduced in the event of heavy snow loads.

In a preferred further embodiment, tubes of different cross-sections are arranged on opposite outer lateral sections of the leporello folding. This also allows the roll angle of the leporello folding to be adjusted around the unfolding direction.

In a further embodiment of the invention, a different number of tubes is arranged on opposite outer lateral sections of the leporello folding in one cross-section, preferably each cross-section. This also allows the roll angle to be adjusted as desired.

The hoses are in a cross-section transverse, preferably perpendicular to the unfolding direction, preferably round, particularly preferably circular in each cross-section, and can be filled with a gas, preferably air. However, other gases for filling are also conceivable in principle.

The outer skin of a hollow body that can be inflated with a gas is preferably designed as a gas-tight fabric sheet, which is inflated in an operating state and is designed to support the solar panels that can be folded like a leporello folding. Air or nitrogen is preferably used as the gas.

Preferably, hoses are arranged next to and/or on top of each other in bundles transverse to the unfolding direction on opposite lateral sections of the leporello folding. In principle, it is advantageous to provide the hoses at least in pairs in order to create redundancy. The redundancy, together with the detachable fastening, also makes it possible to replace hollow bodies during operation. Furthermore, the roll angle of the leporello folding can be adjusted by arranging several hoses on top of each other.

Preferably, at least one hollow body that increases in height against the unfolding direction is provided. This allows the pitch angle of the leporello folding to be adjusted individually.

In another variant of the solar plant, a row of hollow bodies is provided next to each other in the unfolding direction. The hollow bodies are preferably extensive, in particular cushion-shaped or mattress-shaped. Evaporation is reduced by extensive hollow bodies that cover as large an area of water as possible, so that this type of design helps to conserve water resources. Extensive hollow bodies on sloping or horizontal roofs enable a more even load distribution, so that the maximum load-bearing capacity of buildings can be more easily maintained when using such systems. In addition, extensive hollow bodies act as insulation.

Preferably, the hollow bodies filled with gas or foam distribute loads on roofs or other load-sensitive surfaces relatively evenly, so that the stability of the surface is guaranteed. Variable ballasting of the hollow bodies and pockets allows the current loads to be adjusted, for example due to snow or additional installations on a roof.

Preferably, the hollow bodies, which are filled with gas and/or material, for example in a convection-reducing honeycomb structure, with particularly low thermal conductivity, insulate the underlying surface from the surface.

Preferably, watertight connected solar panels, for example by means of watertight glued tabs and/or a watertight substructure, for example a film, protect the underlying surface against weather influences such as rain, dew or snow.

The cushion-shaped or mattress-shaped hollow bodies can become wedge-shaped higher at right angles to the unfolding direction and thus set a roll angle. In the case of an approximately east-west oriented unfolding direction, the lower side of the hollow bodies is turned towards the equator, so that the solar yields increase due to more favorable solar angles of incidence. If the wedge is aligned in the unfolding direction, a pitch angle is set. In the case of an approximately north-south aligned unfolding direction, the lower side of the hollow bodies is turned towards the equator, so that the solar yields increase due to more favorable solar angles of incidence.

Preferably, adjacent edges of neighbouring solar panels of the leporello folding are connected to each other by means of flexible or hinged connections. This embodiment is particularly simple and cost-effective. The tabs can be made of textile or plastic material.

Preferably, the solar plant is intended to float on water in the operating state, for example it can be set to the operating state on a lake or sea. However, in another embodiment, it is also conceivable to set up the solar plant on the ground, for example on a fallow field. In both cases, the solar plant according to the invention allows the solar plant to be quickly set up in the operating state and quickly dismantled in a transport state. Due to the rapid dismantling of this type of solar plant, it can be used particularly favourably for temporary applications and can also be more easily recycled at the end of its service life.

Preferably, the leporello folding is folded together in the transport state, and sections of the at least one hollow body arranged between two adjacent solar panels are each arranged between the two adjacent solar panels. As a result, the solar panels and the hollow bodies are protected during transportation, and the entire solar plant including the hollow bodies can be folded.

In a preferred embodiment of the invention, at least one pump permanently remaining with the solar plant is provided, which enables one or more of the hollow bodies to be filled with gas.

In a particularly preferred further embodiment of the invention, a pump is provided between a hollow body and a hollow body separated from it in a gas-tight manner, which enables the gas to be pumped from one hollow body into the other or vice versa. In particular, a control system can be provided which is connected to the pumps in a data-conducting manner and enables the position of the solar panels to be changed in relation to the ground in view of the position of the sun. Preferably, the gas is pumped in and out from western hollow bodies to eastern hollow bodies during the course of the day. In the case of leporello systems arranged approximately east-west, the inclination to the sun can be changed by pumps over the course of the year. As a result, the leporello folding follows the position of the sun and a greater electricity yield is achieved.

Preferably, the hollow bodies are exchangeably arranged on the solar panels. Velcro, screw, clamp or other detachable fasteners can be provided.

Preferably, winches are provided for pulling out the solar panels, which are further away from the ground than the attachment points of the flexible substructure on the solar panels.

Preferably, sensors such as temperature and/or pressure and/or humidity sensors are provided in hollow bodies filled with gas or liquid, which are connected to an alarm system. If there are leaks in the gas-filled hollow bodies, these are detected by evaluating the measured values and an alarm signal is generated and sent to a control center or similar.

The task is fulfilled in its second aspect by a method mentioned at the beginning with the features of claim 26.

The method is suitable for setting up the above-mentioned solar plants and, conversely, each of the above-mentioned solar plants is suitable for carrying out one of the methods described below. What has been said about the device also applies mutatis mutandis to the method and vice versa.

The method is suitable for setting up a solar plant with solar panels arranged in a leporello folding by moving the folded solar plant to the location, pulling out a substructure that is designed to be flexible in one unfolding direction and connected to the solar panels in a fixed position, and unfolding the leporello folding.

The solar plant is brought to the location in a transport state, i.e. folded up, and preferably aligned there. Preferably, transport locks are gradually released, the substructure is pulled out and the leporello folding unfolds.

The method according to the invention makes use of the idea of providing a simple and time-saving and thus also cost-effective method for setting up a solar plant. The solar plant can be set up by the method floating on water or on solid ground.

Preferably, the leporello folding unfolds automatically by pulling out the substructure.

The method is characterized by the fact that by inflating the hollow bodies, the leporello foldable solar panels preferably automatically unfold to the correct inclination angle and also in the correct orientation due to the pre-positioning of the solar plant.

Preferably, hollow bodies leading in the unfolding direction are first filled with a medium and then hollow bodies trailing in the unfolding direction are filled with the medium. A gas, a liquid or hardening foam can be used as the medium.

It is particularly preferable for the solar plant to be positioned in such a way that a container with the folded solar plant is arranged directly next to the water surface or already a little way into the water, so that the inflatable hollow bodies can easily unfold along the water surface and the solar panels are drawn into the water by successively filling the hollow bodies or chambers of hollow bodies arranged one behind the other in the unfolding direction. Other filling sequences are also conceivable, in particular chambers can also be inflated slowly at the same time. The leporello folding system can also be transported to the installation site on ships or barges/carrier ships without propulsion and deployed from there on the water surface.

Preferably, the solar plant is extended into a body of water and the hollow bodies are dimensioned in such a way that the solar plant floats in the water with the hollow bodies. It is therefore preferable that the leading hollow bodies are first inflated to such an extent that they can support the weight of the solar panels arranged on them.

In principle, however, it is also conceivable with regard to the method that the solar plant is not installed on a body of water, but on a solid surface, preferably an inclined or horizontal roof, field or similar.

Preferably, a sheet can then be used as the substructure. The sheet can be a textile sheet, a rope or a plurality of these.

Friction-reducing mats can be laid out in advance on the solid surface. However, the mats also serve to protect the hollow bodies from friction damage. This applies in particular if the solar plant is installed on the roof of a house or on other adhesive or rough surfaces.

To facilitate assembly on a solid surface, the successively inflated hollow bodies can be successively placed on rolling devices. The rolling devices make it easier to pull out the hollow bodies.

A monitoring system continuously measures status variables such as pressure, temperature and humidity in the hollow bodies, determines the current position of the system or scans high-frequency accelerations in order to record flow-, wind-or wave-induced movements. This allows the ageing of the system to be documented, loosened anchorages to be detected and leaks to be identified at an early stage. If critical thresholds are exceeded, maintenance alarms can be triggered and sent automatically.

A control system can control pumps and valves which, by pumping the medium from a hollow body into a hollow body separated from it by a medium-tight seal, track the position of the leporello folding according to the position of the sun, in particular by changing the roll angle of the leporello folding during the course of the day or year. The pumps can also fill individual hollow bodies separately with the medium or empty them-

Ideally, electricity yields and yield-relevant environmental parameters such as radiation intensity and/or module temperatures and/or wind are measured continuously and the current system efficiency is determined algorithmically from the measured values and an alarm signal is issued in the event of low system efficiency or other system faults and this data is documented continuously.

Preferably, the current geodetic positions of the leporello systems are permanently measured and recorded in absolute terms and relative to each other, and accelerations and angles are permanently measured at high frequency, and/or water depth, waves, currents, water temperature profiles, water constituents and chemical and physical water parameters are permanently measured in order to document current-, wind-or wave-induced movements.

Preferably, electricity yields and yield-relevant environmental parameters such as radiation intensity and/or module temperatures and/or wind are measured continuously and the current system efficiency is determined algorithmically from the measured values and an alarm signal is issued in the event of low system efficiency or other system faults being detected and this data is documented continuously.

The invention is described with reference to several embodiments in 22 figures. They show:

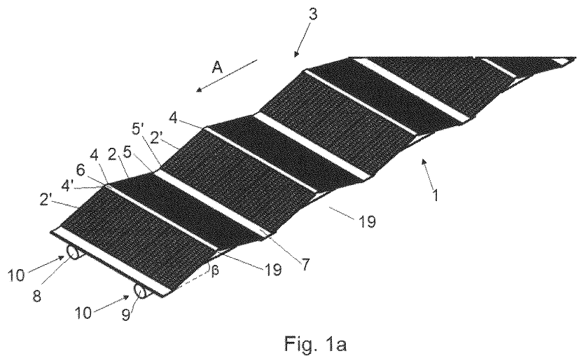

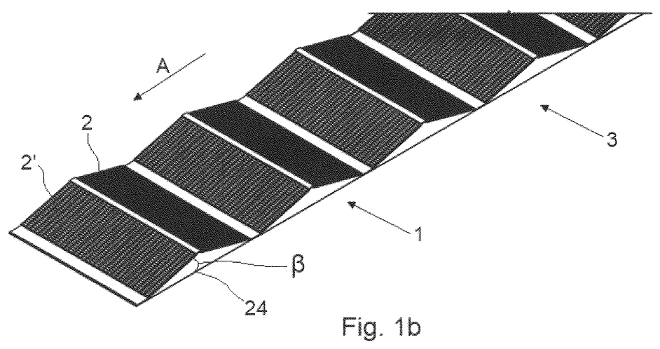

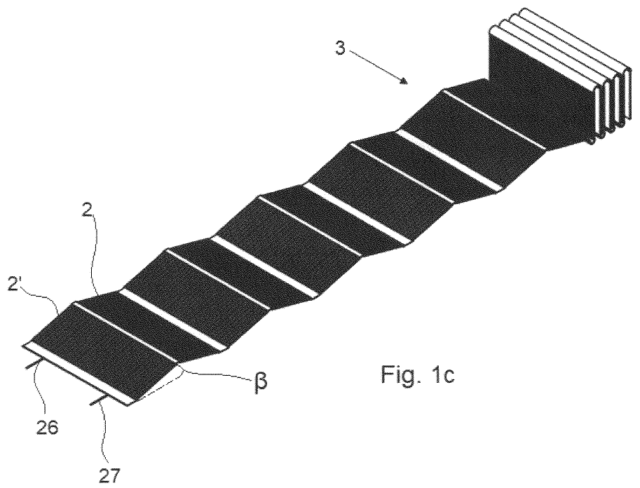

FIG. 1a perspective view of a solar plant according to the invention on two hollow bodies,

FIG. 1b solar plant according to the invention in a second embodiment on a sheet,

FIG. 1c a solar plant according to the invention in a third embodiment on two belts,

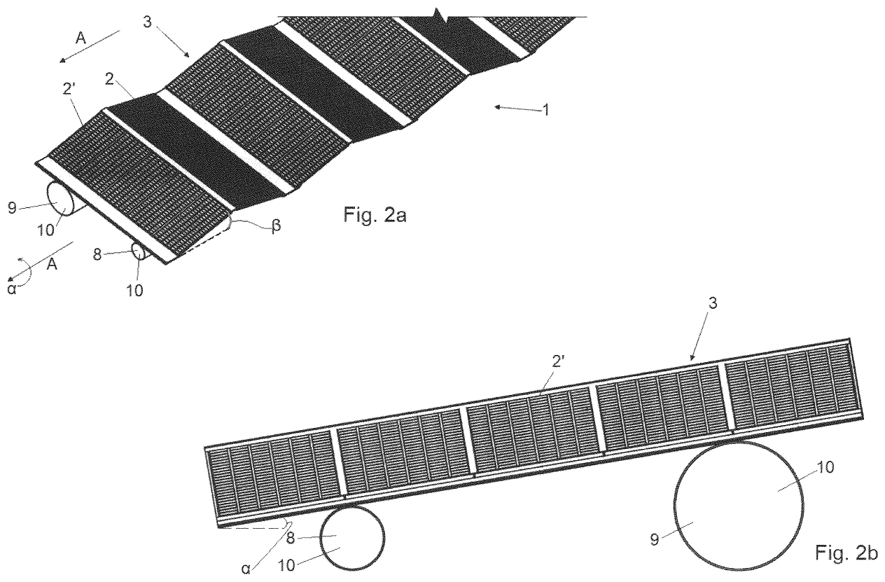

FIG. 2a a fourth embodiment of the solar plant,

FIG. 2b a longitudinal sectional view of the solar plant in FIG. 2a,

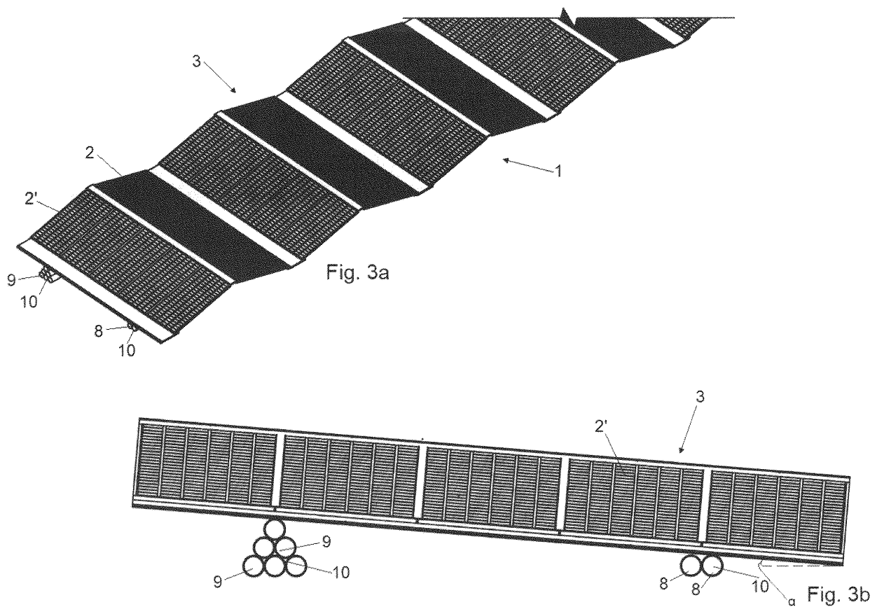

FIG. 3a a fifth embodiment of the solar plant,

FIG. 3b a longitudinal sectional view of the solar plant in FIG. 3a,

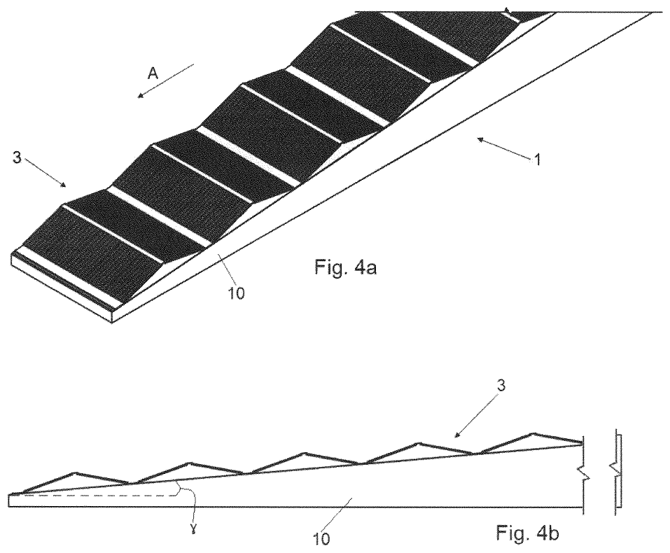

FIG. 4a a sixth embodiment of the solar plant,

FIG. 4b a longitudinal sectional view of the solar plant in FIG. 4a,

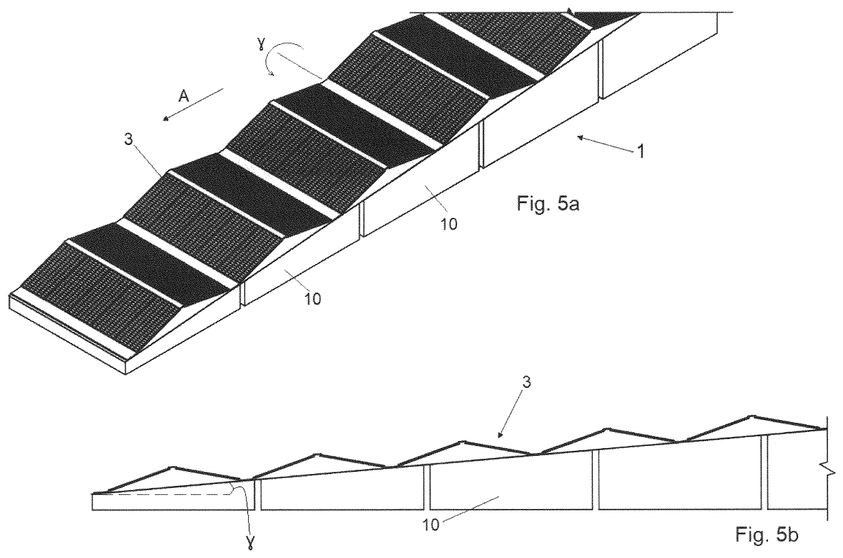

FIG. 5a a seventh embodiment of the solar plant,

FIG. 5b a longitudinal sectional view of the solar plant in FIG. 5a,

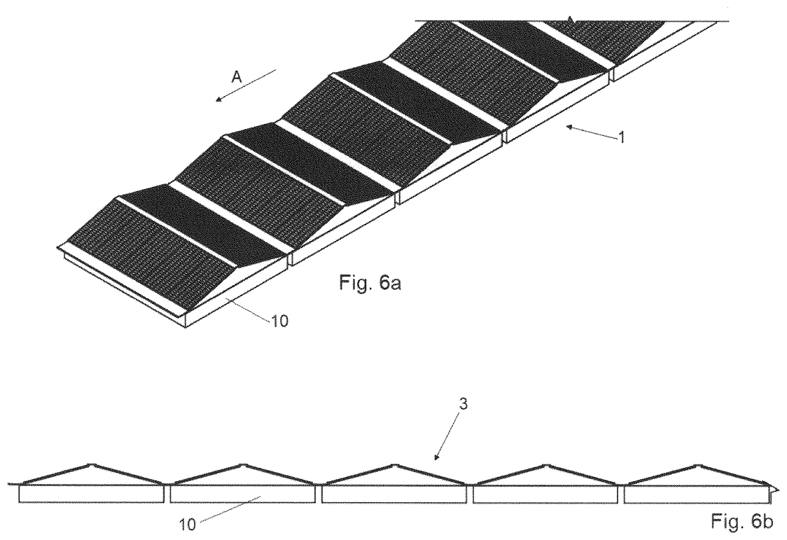

FIG. 6a an eighth embodiment of the solar plant,

FIG. 6b a longitudinal sectional view of the solar plant in FIG. 6a,

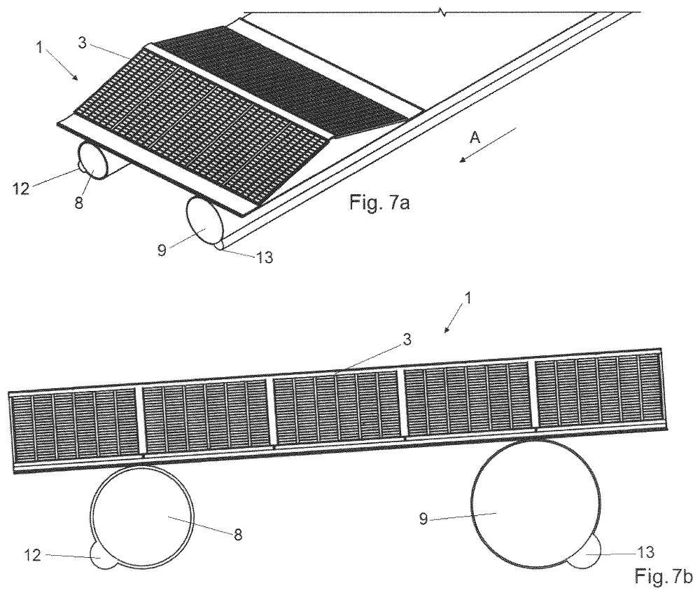

FIG. 7a a ninth embodiment of the solar plant according to the invention in a perspective view for support on a solid surface,

FIG. 7b a cross-sectional view of the solar plant in FIG. 7a,

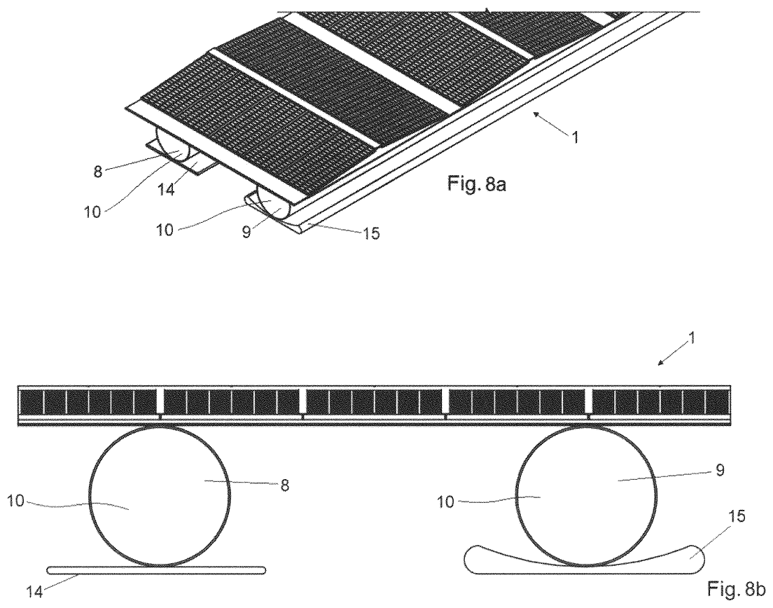

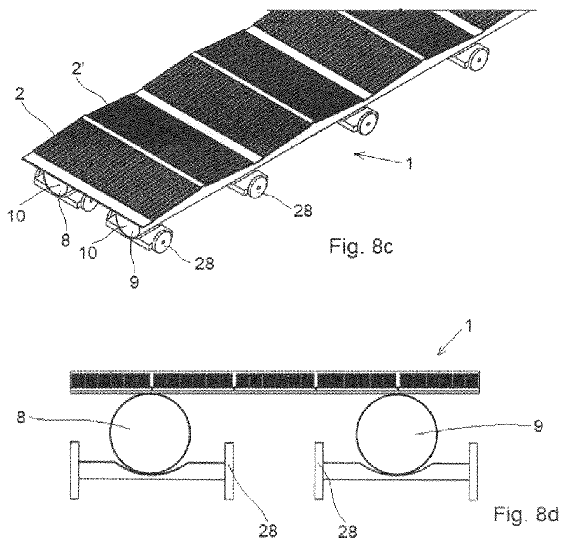

FIG. 8a a perspective view of the solar plant in a tenth embodiment for support on a solid surface,

FIG. 8b a sectional view of the solar plant in FIG. 8a,

FIG. 8c a solar plant in an eleventh embodiment,

FIG. 8d a sectional view of the solar plant in FIG. 8c,

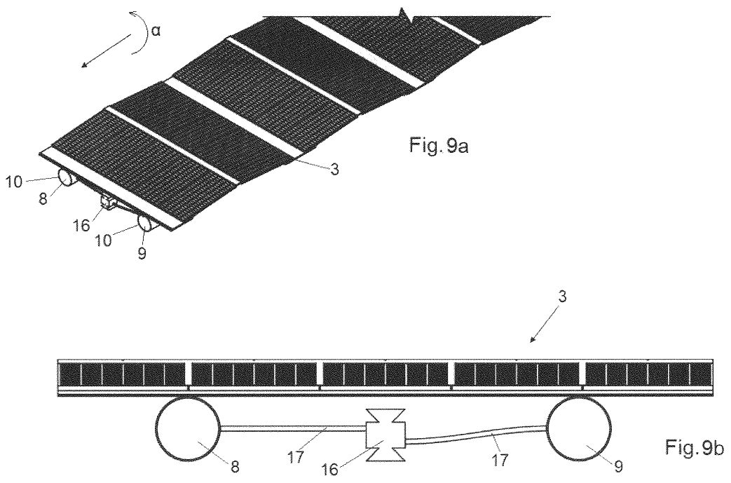

FIG. 9a a perspective view of the solar plant with a pump,

FIG. 9b a sectional view of the solar plant in FIG. 9a,

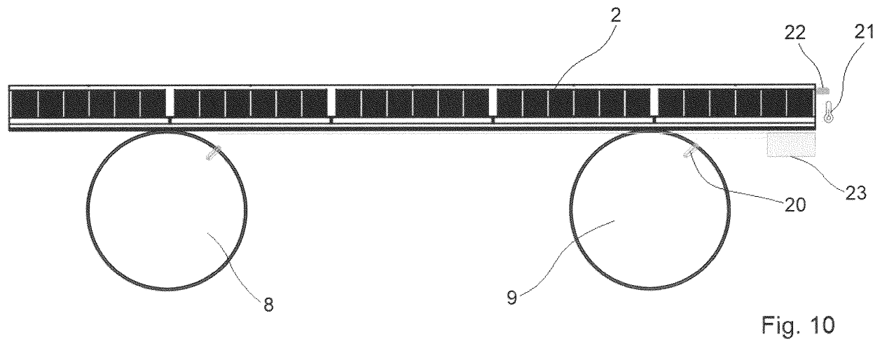

FIG. 10 solar plant with sensors.

A solar plant 1 according to the invention has solar panels 2, 2′ which are arranged in a leporello folding 3. The leporello folding 3 can be extended in an unfolding direction A and folded in the opposite direction to the unfolding direction A. In the embodiment shown in FIG. 1a, the leporello folding 3 has solar panels 2, 2′ arranged next to each other. Each roof side of the leporello folding 3 is designed as a solar panel 2, 2′. Leporello folding 3 is understood here to be the solar panels 2, 2′ arranged next to one another in the direction of unfolding A, which have edges 4, 4′ on the off-substructure side and edges 5, 5′ on the substructure side. The solar panels 2, 2′ are articulatedly connected to each other at the edges 4, 4′ facing away from the substructure by a short flap 6 and at the edges 5, 5′ facing away from the substructure by a long flap 7. The short flap 6 is shorter in the unfolding direction A than the long flap 7. The leporello folding 3 is arranged on a substructure with two inflatable hoses 8, 9, which act as inflatable hollow bodies 10. For this purpose, the long flaps 7 on the substructure side are fixed in position on the hoses 8, 9, for example glued on or otherwise arranged. The foremost or rearmost solar panels in the unfolding direction A also each have a flap on their substructure side edge 5, 5′, which is fixed to the hoses 8, 9.

Each solar panel 2, 2′ consists of a large number of individual solar cells arranged in a grid. The wiring of the individual solar cells and the connection of the solar panels 2, 2′ to a power grid are not shown.

The solar plant 1 in FIGS. 1a, 1b, FIGS. 2a, 2b, FIGS. 3a, 3b, FIGS. 4a, 4b, FIGS. 5a, 5b and FIGS. 6a, 6b is designed to float on water. It is a floating solar plant 1. The hollow bodies 10 are dimensioned in such a way that they generate sufficient buoyancy so that the leporello folding 3 is arranged completely above a water surface. The hollow bodies 10 themselves preferably protrude from the water surface with a section along their entire extension length. The solar plant 1 is therefore particularly suitable for use as a floating solar plant 1 in calm waters, preferably in lakes that have a low swell.

The hollow bodies 10 of floating solar plants 1 are generally and also in this embodiment completely or partially filled with air or another gas or foam.

In particular, the application of a leporello folding 3 on water has the additional beneficial effect of reducing evaporation of the water in very warm areas through shading and covering. It is conceivable to arrange a flexible intermediate sheet (not shown), which is preferably reflective, underneath the leporello folding 3 so that light radiation passing through the solar panels 2, 2′ is reflected back, thereby increasing the power efficiency of the solar plant 1 and also reducing the evaporation of the water underneath.

The solar panels preferably have an inclination angle β of 10° to 15° when they are aligned east-west and a flatter inclination angle β when they are aligned north-south. In north-south orientation, the inclination angle β can also disappear to zero. Other angles are also conceivable.

FIG. 1b shows a second embodiment of the solar plant 1 according to the invention. The second embodiment differs from the first embodiment of the solar plant 1 according to the invention in that it has a different substructure. In the second embodiment, the substructure comprises a sheet 24 which is flexible at least in the unfolding direction A and which is continuous in the unfolding direction A. At predetermined intervals, two solar panels 2, 2′ are fixed in position on the flexible sheet 24, so that the sheet, when fully extended as shown in FIG. 1b, forces the two adjacent solar panels 2, 2′ into a roof position, the pitch of the roof having a predetermined angle β. The flexible sheet 24 is a flexible sheet that can be folded up in sections between two adjacent solar panels 2, 2′ when folded in.

FIG. 1c shows a third embodiment of the solar plant 1 according to the invention. The third embodiment also differs from the first embodiment in FIG. 1a and the second embodiment in FIG. 1b in that the substructure is implemented differently. The sheet 24, which is flexible or slack in the unfolding direction A, is selected here as two belts or ropes 26, 27, which are fully extended at least at the left end in the state shown in FIG. 1c and thus also force neighbouring solar panels 2, 2′ into a roof angle with a roof pitch β.

For the substructures, the at least one flexible sheet 24 and the ropes 26, 27 can of course be formed in other ways. Several belts or ropes 26, 27 can be used, several flexible sheets 24 can be used or a combination thereof, to name but a few.

FIG. 2a shows the same basic structure of a solar plant 1 as described in FIG. 1a. The leporello folding 3 has a larger number of solar panels 2, 2′. Only two solar panels 2, 2′ are shown in FIG. 2a. The solar plant 1 also has two hollow bodies 10, which are designed as hoses 8, 9. Both hoses 8, 9 are preferably completely filled with gas. However, the hoses 8, 9 have different cross-sections, so that the leporello folding 3 of the floating solar plant 1 is tilted by a roll angle α over its entire length along the unfolding direction A. The solar plant 1 of FIG. 1 and of FIG. 2 is preferably oriented in an east-west direction. This means that the unfolding direction A, i.e. also the orientation of the two hoses 8, 9, is in the east-west direction.

In FIG. 2a and FIG. 2b, the leporello folding 3 is tilted by the roll angle α, preferably in the direction of the equator, in order to increase the overall efficiency of the solar plant 1. The hose 9 on the side away from the equator has a larger cross-section than the hose 8 on the equator side.

The tilting of the leporello folding 3 towards the equator can also be achieved according to the embodiments in FIGS. 3a, 3b by using hoses 8, 9 with the same cross-section, but the side of the leporello folding 3 facing away from the equator rests on a bundle with a larger number of hoses 8 than the side of the leporello folding 3 facing the equator. Only one hose 8 or two hoses 8 are provided on the side facing the equator, which are also arranged horizontally next to each other, while the hose bundle on the side facing away from the equator has hoses 9 arranged next to and, above all, above each other, so that the leporello folding 3 protrudes further above the water surface on the side facing away from the equator than on the side facing the equator.

The embodiments in FIGS. 4a, 4b, FIGS. 5a, 5b and FIGS. 6a, 6b show a solar plant 1 with cushion-like or mattress-like hollow bodies 10. They are vertical in cross-section and rectangular in the unfolding direction A with rounded corners. The mattress-shaped hollow bodies 10 are separated from each other and exactly one mattress-shaped hollow body 10 is provided under each pair of solar panels 2, 2′.

The hollow bodies 10 in the solar plants 1 shown in FIGS. 4, 4a and FIGS. 5, 5a have a height that increases in the opposite direction to the unfolding direction A, so that the solar plant 1 as a whole is tilted by a pitch angle γ in the unfolding direction A when the solar plant 1 floats on the water. A small pitch angle γ can be particularly useful if the hoses 8, 9 or the unfolding direction A are oriented north-south in order to increase the overall efficiency of the solar plant somewhat.

In principle, what has been said about the roll angle α and the pitch angle γ as well as the inclination angle β also applies to solar plants 1 that stand on a solid surface.

The solar plant 1 in FIGS. 1a, 2a and 3a has hollow bodies 10, preferably in the form of hoses 8, 9, as a substructure. The hoses are dimensioned in such a way that they are filled with air or another gas, for example nitrogen, and generate sufficient buoyancy so that the entire solar plant floats on the surface of a body of water. In principle, the aforementioned constructions with the hollow bodies 10 in FIGS. 1a, 2a, 3a can also be used on solid or boggy ground, but also on house roofs. In cases where the ground is solid, the cross-section of the buoyancy bodies can be smaller, as they do not have to generate buoyancy to keep the entire solar plant above water. Particularly in the case of construction on house roofs, it may be intended to completely fill the hollow bodies with a foam that hardens after foaming, so that the weight of the solar panels is evenly distributed over the longitudinal extent of the two or more hollow bodies 10.

In the embodiment shown in FIGS. 4a, 4b, precisely one inflatable hollow body 10 is provided, which has a wedge-shaped structure in longitudinal section in the unfolding direction A. Like all other hollow bodies 10, the interior of the hollow body 10 can of course have chambers that are not shown.

The embodiment in FIGS. 5a, 5b also shows a solar plant, preferably in a north-south orientation, whereby a plurality of cuboidal hollow bodies 10 is provided here, each of which has a wedge-shaped form in longitudinal section and which in their overall arrangement form a wedge-shaped form in the unfolding direction A.

FIGS. 6a, 6b show the solar plant 1 with individual hollow bodies 10 arranged one behind the other in the unfolding direction A, which are all of identical construction and cubic in shape and have a constant height over the entire extension. If the mattress-shaped hollow bodies 10 are selected as the substructure, this solar plant 1 can also be used on solid surfaces. Here too, the hollow bodies 10 are preferably smaller in size and filled with hardening foam, so that buoyancy no longer needs to be generated.

FIGS. 7a, 7b and FIGS. 8a, 8b describe two embodiments of the solar plant 1, which are intended in particular for installation on a solid surface. This can be an area that is only temporarily flooded, permanently and temporarily soaked ground, solid ground, surfaces with a steep slope or a roof, preferably a flat roof of a building.

To ballast the solar plant 1, hoses 8, 9 in FIGS. 7a, 7b can be filled with liquid, for example water with glycol. They can be completely or partially filled. Filling with foam or granular material is also possible. Conveniently, a pocket 12, 13 extending over the entire or only parts of the entire unfolding direction A is provided on the outside of each of the two hoses 8, 9, which can also be filled with ballast material and thus counteract the lifting of the solar plant 1 in windy conditions. In addition, it reduces the possibility of the wind undercutting the hoses 8, 9.

FIGS. 8a, 8b also show a solar plant 1 that is installed on a solid surface. Flat roofs in particular have a roughness that could damage the hollow bodies 10, so that a support mat 14 can be placed under the one hollow body 10. This could be a textile or plastic mat, for example. The other hollow body 10 is placed along a bearing 15. The bearing 15 is shown in FIG. 9a below the right hose 9. The bearing 15 has a convex surface so that the hose 9 slides back into a certain desired position after unintentional slipping.

A curvature of the concave bearing 15 is adapted to a curvature of the hose, and wheels can also be provided on the side of the concave bearing 15, so that the entire solar plant 1 or the hose 9 can be moved over the solid surface during inflation. It may also be provided that the support mat 14 is again arranged below the bearing 15, on which the concave bearing 15 can be moved with the lateral wheels.

FIGS. 8c and 8d show a further variant of the solar plant 1. The hollow bodies 10 are designed as hoses 8, 9 and are extended on small trolleys 28 in the unfolding direction A. For example, leading sections of the hoses 8, 9 can also be inflated first or the hoses 8, 9 are only partially inflated and successively extended on the trolley 28 in the unfolding direction by releasing transport clamps between the individual solar panels 2, 2′. After unfolding, the trolleys 28 can remain in place or be removed.

FIGS. 9a, 9b show a further development of the solar plant 1. A pump 16 can be provided between different, separate hollow bodies 10, for example the two hoses 8, 9 shown in FIG. 9a, which pumps air from one hose 8 into the other hose 9. Particularly with a north-south orientation of the solar plant 1, the western hose 8 is preferably more inflated in the morning than the eastern hose 9, so that the roll angle α, which tilts the leporello folding 3 to the east, is present, while the pump continuously tracks the roll angle α to the sun during the course of the day and in the evening the eastern hose 9 is more inflated than the western hose 8, so that a tilt by a roll angle α to the west is present. The pump 16 is connected to the hollow bodies 10 by means of pump hoses 17.

While pumping over during the course of the day significantly increases efficiency when the solar plant is aligned north-south, the wedge-shaped form of the hollow bodies 10 in the embodiments shown in FIGS. 4a, 4b and FIGS. 5a, 5b, for example, means that pumping around is not necessary and efficiency is increased by permanently tilting the solar plant 1 towards the equator.

The solar plant 1 is folded up in the leporello folding 3 for transportation. The folded solar plant 1 is housed in a container, for example. To assemble the solar plant 1, a side wall of the container is folded out and the two hollow bodies 10 are filled with air. Preferably, the hollow bodies 10 have separate chambers in the unfolding direction A, and the chambers of the hollow bodies 10 leading in the unfolding direction A are first filled with air, so that the first two or first few solar panels 2, 2′ are pulled out of the container through the inflating chambers of the hollow bodies 10 and are automatically brought into their unfolded structure by inflating the hollow bodies 10. Preferably, the container is already positioned in or near the water for this purpose, and the hollow bodies 10 can be pushed into the water in the unfolding direction A by the inflation. The hollow bodies 10 can be inflated using a pump.

If the solar plant 1 is installed on solid ground, the support mats 14 can first be laid on the solid ground, on which the inflating hollow bodies 10 then slide along. The hollow bodies 10 are preferably filled with water or foam. Filling with water or foam is also understood by the term inflating.

It is also conceivable that the hoses 8, 9 are placed successively as hollow bodies 10 on wheeled bearings, preferably with a concave contact surface, and then moved over the floor or over the support mat 14 laid out on the floor in the unfolding direction A.

FIG. 11 shows an arrangement of sensors in the hollow bodies 20, sensors for measuring environmental parameters 21 outside the hollow bodies and radiation measuring devices 22 on the solar plant 1. The arrangement of sensors 20, 21, 22 is particularly suitable in connection with inflatable hoses 8, 9, which form buoyant bodies and on which the entire solar plant 1 floats on the water. Here it makes sense to constantly monitor the condition of the inflated hoses 8, 9 and to send out an alarm in the event of defects in the hoses 8, 9 and a reduction in buoyancy. Measuring sensors 20 such as pressure sensors, temperature sensors, humidity meters are therefore provided in the hoses 8, 9, and measuring sensors 21 such as temperature sensors, humidity meters can be provided outside the hoses 8, 9. Radiation measuring devices 22 are also provided. Measured data is collected in a data logger 23 and fed to a data logger whose combined measured values make it possible to determine whether a pressure drop or a pressure increase is caused only by the temperature change or by an air leak in the hoses 8, 9.

### LIST OF REFERENCE SYMBOLS

1 Solar plant
2 Solar panel
2′ Solar panel
3 Leporello folding
4 Edge on the off-substructure side
4′ Edge on the off-substructure side
5 Edge on the substructure side
5′ Edge on the substructure side
6 Short flap
7 Long flap
8 Hose
9 Hose
10 Hollow body
11 Reinforcement
12 Pocket
13 Pocket
14 Support mat
15 Bearing
16 Pump
17 Pump hoses
18 Roller system
20 Sensor in hollow body
21 Sensors for measuring environmental parameters
22 Radiation measuring devices
23 Data logger
24 Flexible sheet
26 Belt, rope
27 Belt, rope
28 Trolleys
α Roll angle
γ Pitch angle
β Inclination angle
A Unfolding direction

1. Solar plant with solar panels (2, 2′) which are arranged in a leporello folding (3) which can be unfolded in an unfolding direction (A), and a substructure (8,9,10. 24) on which the solar panels are arranged, characterized in that the substructure is designed to be flexible in the unfolding direction (A) and is connected to the solar panels in a positionally fixed manner such that the leporello folding (3) of the solar panels can be unfolded with the substructure (8, 9, 10, 24) and determines an angular positions of the solar panels (2, 2′) relative to one another in an unfolded state.

2. Solar plant according to claim 1,
characterized in that the leporello folding (3) of the solar panels (2, 2′) can be automatically unfolded with the substructure (8, 9, 10, 24).

3. (canceled)

4. Solar plant according to claim 1, characterized in that the substructure (8, 9, 10, 24) has, in the unfolded state, at least one flexible hollow body (10) which extends in the unfolding direction (A) and can be filled with a medium.

5. (canceled)

6. (canceled)

7. Solar plant according to claim 4 characterized in that the flexible hollow bodies (10) filled with a medium generate sufficient buoyancy to hold the solar panels (2, 2′) above a water surface of a body of water in which the solar plant (1) floats.

8. (canceled)

9. Solar plant according to claim 4,
characterized in that the flexible hollow body which can be filled
with a medium has a plurality of hoses (8, 9) which are arranged next to one another transversely to the unfolding direction (A) and each extend in the unfolding direction (A).

10. Solar plant according to claim 4, characterized in that the hollow bodies (10) can be permanently filled with foam.

11. (canceled)

12. (canceled)

13. (canceled)

14. Solar plant according to claim 1, characterized in that one or a row of hollow bodies (10) are provided side by side in the unfolding direction (A).

15. (canceled)

16. Solar plant according to claim 1, characterized in that the leporello folding (3) is folded in a transport state and sections of the flexible substructure (10) arranged between two adjacent solar panels (2, 2′) are arranged between the two folded adjacent solar panels (2, 2′).

17. (canceled)

18. (canceled)

19. (canceled)

20. (canceled)

21. Solar plant according to claim 3, characterized in that at least one pump (16) permanently remaining with the solar plant (1) is provided, which enables the hollow bodies (10) to be filled or emptied with gas.

22. (canceled)

23. Solar plant according to claim 3, characterized in that hollow bodies (10) are interchangeably arranged on the solar panels (2. 2′).

24. (canceled)

25. (canceled)

26. Method for assembling a solar plant (1) with solar panels (2, 2′) arranged in a leporello folding (3) by moving the folded solar plant (1) to a location, a substructure (8, 9, 10, 24) flexibly connected to the solar panels (2, 2′) in a fixed position in one unfolding direction is pulled out and the leporello folding (3) unfolds and the angular positions of the solar panels (2, 2′) relative to one another are determined.

27. Method according to claim 26, characterized in that the leporello folding (3) is automatically unfolded by unfolding the substructure (8, 9, 10, 24).

28. Method according to claim 26, characterized in that hollow bodies (10) leading in the unfolding direction (A) are first filled with a medium and then hollow bodies (10) trailing in the unfolding direction (A) are filled with the medium.

29. (canceled)

30. (canceled)

31. (canceled)

32. The method according to claim 28, characterized in that physical state variables and/or the chemistry are permanently measured in hollow bodies (10) filled with gas, foam or liquid and the states of the hollow bodies (10) are determined from measured values and an alarm signal is emitted in the event of an algorithmically determined fault or significant ageing and the system states and conditions are continuously documented.

33. (canceled)

34. (canceled)

35. The method according to claim 26, characterized in that electricity yields and yield-relevant ambient parameters such as radiation intensity and/or module temperatures and/or wind are measured continuously (10) the current system efficiency is determined algorithmically from the measured values and an alarm signal is output in the event of determined low system efficiency or other system faults and this data is documented continuously.
